(19) United States
(12) Patent Application Publication
(10) Pub. No.: US 2010/0176728 A1
(43) Pub. Date: Jul. 15, 2010

(54) HIGH-PRESSURE DISCHARGE LAMP COMPRISING A HIGH-VOLTAGE IMPULSE GENERATOR AND METHOD FOR PRODUCING A HIGH-VOLTAGE IMPULSE GENERATOR

(76) Inventors: Andreas Kloss, Neubiberg (DE); Steffen Walter, Oberpframmern (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/663,496

(22) PCT Filed: Jun. 2, 2008
(86) PCT No.: PCT/EP08/56749

§ 371 Date: Dec. 7, 2009

(30) Foreign Application Priority Data
Jun. 6, 2007 (EP) PCT/EP2007/055544

(51) Int. Cl. H01J 61/54; H03K 3/00; B05D 3/06; B05D 5/12

(52) U.S. Cl. 315/56; 307/106; 427/553; 427/130

(57) ABSTRACT

A coating method for coating a spiral pulse generator with a ferritic layer, wherein the spiral pulse generator is surrounded by a ferritic compound that is cured by heat or UV radiation.

### TECHNICAL FIELD

The invention proceeds from a high voltage pulse generator in accordance with the preamble of claim 1. Such generators can be used, in particular, for starting high pressure discharge lamps for general illumination or for photooptical purposes or for motor vehicles. The invention also relates to a high pressure discharge lamp having such a generator, and to a method for the production thereof.

### PRIOR ART

The problem with starting of high pressure discharge lamps is at present solved by the starting device being integrated in the ballast. One disadvantage of this is the fact that the supply leads need to be designed so as to be able to withstand high voltages.

In the past, repeated attempts have been made to integrate the starting unit in the lamp. These attempts have included attempts to integrate the starting unit in the base. Particularly effective starting which promises high pulses has been successful by means of so-called spiral pulse generators; see U.S. Pat. No. 3,289,015. A relatively long time ago, such devices were proposed for various high-pressure discharge lamps such as metal halide lamps or sodium high pressure lamps; see U.S. Pat. No. 4,325,004, U.S. Pat. No. 4,353,012, for example. However, they could not gain acceptance since, firstly, they are too expensive. Secondly, the advantage of incorporating them

in the base is insufficient since the problem of feeding the high voltage into the bulb remains. For this reason, the probability of damage to the lamp, whether it be insulation problems or a breakdown in the base, increases severely. Starting devices which have been conventional to date generally could not be heated above 100° C. The voltage generated would then have to be fed to the lamp, which requires lines and lampholders with a corresponding high-voltage strength, typically approximately 5 kV. A double generator can be used to generate particularly high voltages—see U.S. Pat. No. 4,608,521.

In conventional starter circuits, a capacitor is normally discharged via a switch, for example a spark gap, into the primary winding of a starting transformer. The desired high voltage pulse is then induced in the secondary winding. See to this end Sturm/Klein, Betriebsgeräte and Schaltungen für elektrische Lampen [Operating devices and circuits for electric lamps], pages 193 to 195 (6th edition 1992).

### OBJECT

The object of the present invention is to specify a spiral pulse generator that can be used as a high temperature-proof pulse generator of very compact design.

This object is achieved by the characterizing features of claim 1.

A further object is to specify a method for producing such a compact spiral pulse generator.

This object is achieved by the characterizing features of claim 9.

A further object is to provide a high pressure discharge lamp whose starting behavior is greatly improved by comparison with previous lamps, and in the case of which no damage is to be feared as a consequence of the high voltage. This is true, in particular, of metal halide lamps, it being possible for the material of the discharge vessel to be either silica glass or ceramic.

This object is achieved by the characterizing features of claim 15.

Particularly advantageous configurations of the invention are given in the dependent claims.

### DESCRIPTION OF THE INVENTION

According to the invention, a high-voltage pulse with at least 1.5 kV, which is necessary for starting the lamp, is now generated by means of a special temperature-resistant spiral pulse generator, which is integrated in the direct vicinity of the discharge vessel in the outer bulb. Not only cold starting but also hot restarting is therefore possible.

The spiral pulse generator now used is in particular a so-called LTCC component. This material is a special ceramic that exhibits temperature stability up to 600° C. and even up to 1000° C. in particular embodiments. Although LTCC has already been used in connection with lamps (see US 2003/0001519 and U.S. Pat. No. 6,853,151), it was used for entirely different purposes in lamps with virtually hardly any temperature loading, with typical temperatures of below

100° C. The particular value of the high temperature stability of LTCC is apparent in connection with the starting of high-pressure discharge lamps, such as primarily metal-halide lamps with starting problems.

The spiral pulse generator is a component which combines properties of a capacitor with those of a waveguide for generating starting pulses with a voltage of at least 1.5 kV. In order to produce such a spiral pulse generator, two ceramic “green films” are printed with a metallic conductive paste or are provided with a metal foil and then wound in offset fashion to form a spiral and finally isostatically pressed to form a molding. The following co-sintering of metal paste and ceramic film takes place in air in the temperature range between 800 and 900° C. This processing allows a use range of the spiral pulse generator of up to 700° C. temperature loading. As a result, the spiral pulse generator can be accommodated in the direct vicinity of the discharge vessel in the outer bulb, but also in the base or in the direct vicinity of the lamp.

Independently of this, such a spiral pulse generator can also be used for further applications because it is not only stable at high temperatures but is also extremely compact. It is essential for this purpose that the spiral pulse generator be in the form of an LTCC component comprising ceramic films and metallic conductive paste. In order to provide sufficient output voltage, the spiral should comprise at least 5 turns.

In addition, on the basis of this high voltage pulse generator a starting unit can be specified which further comprises

at least one charging resistor and a switch. The switch can be a spark gap or else a diac using SiC technology.

It is preferable in the case of an application for lamps for it to be accommodated in the outer bulb. The reason is that this dispenses with the need for a voltage supply lead that is resistant to high voltages.

In addition, a spiral pulse generator can be dimensioned such that the high voltage pulse even allows for hot restarting of the lamp. The dielectric made from ceramic is characterized by an extremely high dielectric constant ∈ of ∈>10, with it being possible for an ∈ of typically 70, up to ∈=100, to be achieved, depending on the material and design. This allows for a very high capacitance of the spiral pulse generator and enables a comparatively large temporal width of the pulses generated. As a result, a very compact design of the spiral pulse generator is possible, and so success is achieved in installing it in conventional outer bulbs of high pressure discharge lamps.

The large pulse width also facilitates the flashover in the discharge volume.

Any conventional glass cart be used as the material of the outer bulb, that is to say, in particular, hard glass, Vycor or silica glass. The choice of filling is also not subject to any particular restriction.

It has so far been proposed to surround a spiral pulse generator completely or partially by a ferritic material. If the ferritic material has a relative permeability of μr=1 to 5000, the current flowing

through the short circuit in the first winding induces the desired high voltage pulse in the remaining windings of the spiral pulse generator, which is preferably a LTCC generator. It is preferred for μr to be as high as possible, and is at least 10, with particular preference at least 100. The pulse generation effect of the spiral generator itself is surprisingly superposed on this effect. In the case of a spiral generator having n windings, the charging voltage is consequently stepped up (n−1) fold.

To date, an extra ferrite core (pot core, M-core, E-core, I-core), or else a ceramic layer applied using LTCC technology has been used as ferritic casing of the core. These designs have various disadvantages. An extra ferrite core substantially enlarges the design of the generator, and an LTCC ceramic layer is very difficult to apply in the correct orientation.

Consequently, it is proposed in a first embodiment to apply the ferrite material to the spiral pulse generator by means of a dip coating method. This method ensures a uniform, thin ferrite layer that can be adapted in thickness by multiple application of the method. When the method is applied, approximately half of the LTCC generator body is dipped into a low viscosity slurry made from ceramic ferrite material. The processing can be adapted to the application by additives.

A firm and reliable connection to the LTCC generator body results from the fact that the ferrite layer is sintered after the dip coating method.

All conventional materials such as Ba hexaferrites, NiZnCu ferrites and MnZn ferrites can be used as ferrite material.

Depending on the material used, the generator can be temperature stable up to 500° C., and be suitable for installation in an HID lamp, preferably in the outer bulb or in the direct vicinity of the bulb, for example in the base. Further possibilities of the application are, for example, generation of starting pulses for spark ignition engines, high voltage pulses for test purposes (insulation test), and the generation of high voltage pulses for decorative discharges (magic spheres).

In a second embodiment, the spiral pulse generator is embedded completely in a ferritic sealing compound. The polymeric sealing compound is filled in this case with between 10% and 80% of highly permeable ferrite powder. Systems based on acrylic resins, epoxy resins, polyurethane resins or silicone resins come into consideration for the polymeric substance systems. The crosslinking of the sealing compounds can be performed via polymerization, polyaddition, or polycondensation. The starting reaction of the crosslinking can be performed in this case via UV sensitive or thermally activated catalysts or initiators.

### BRIEF DESCRIPTION OF THE DRAWING(S)

The invention will be explained in more detail below with reference to a plurality of exemplary embodiments. In the figures:

FIG. 1 shows the basic design of a spiral pulse generator;

FIG. 2 shows characteristics of an LTCC spiral pulse generator;

FIG. 3 shows the basic design of a sodium high pressure lamp having a spiral pulse generator in the outer bulb;

FIG. 4 shows the basic design of a metal halide lamp having a spiral pulse generator in the outer bulb;

FIG. 5 shows a metal halide lamp having a spiral pulse generator in the outer bulb;

FIG. 6 shows a metal halide lamp having a spiral pulse generator in the base;

FIG. 7 shows a spiral pulse generator encased by a ferrite core;

FIG. 8 shows the voltage profile at a spiral generator connected as a starting transformer;

FIG. 9 shows a spiral pulse generator having a ferrite layer applied using the inventive method;

FIG. 10 shows the voltage profile at a spiral pulse generator that is connected as starting transformer and is encased by a ferritic sealing compound, by comparison with a spiral pulse generator without a ferrite.

### PREFERRED DESIGN OF THE INVENTION

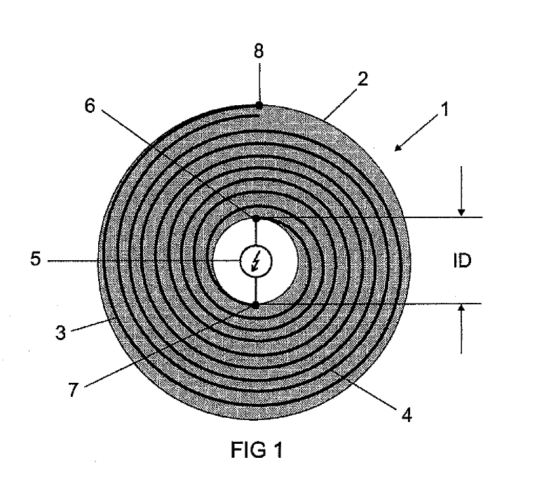

FIG. 1 shows the design of a spiral pulse generator 1 in plan view. It comprises a ceramic cylinder 2 into which two different metallic conductors 3 and 4 are wound in spiral fashion as a foil strip. The cylinder 2 is hollow on the inside and has a given inside diameter ID. The two inner contacts 6 and 7 of the two conductors 3 and 4 are approximately adjacent to one another and are connected to one another via a spark gap 5.

Only the outer one of the two conductors has a further contact 8 on the outer edge of the cylinder. The other conductor ends in open fashion. The two conductors thereby together form a waveguide in a dielectric medium, the ceramic.

The spiral pulse generator is either wound from two ceramic films coated with metallic paste or constructed from two metal foils and two ceramic films. An important characteristic in this case is the number n of turns, which should preferably be of the order of magnitude of from 5 to 100. This coil arrangement is then laminated and subsequently sintered, which results in an LTCC component. The spiral pulse generators created in such a way with a capacitor property are then connected to a spark gap and a charging resistor.

The spark gap can be located at the inner or outer terminals, or else within the winding of the generator. A spark gap can preferably be used as the high voltage switch which

initiates the pulse, which is based on SiC and is very temperature stable. For example, the switching element MESFET from Cree can be used. This is suitable for temperatures over 350° C.

In a specific exemplary embodiment, a ceramic material where ∈=60 to 70 is used. The dielectric used here is preferably a ceramic film, in particular a ceramic strip such as Heratape CT 707 or preferably CT 765, or a mixture of the two, respectively from Heraeus. It has a green film thickness of typically 50 to 150 μm. The conductor used is in particular Ag conductive paste such as “Cofirable Silver”, likewise from Heraeus. A specific example is CT 700 from Heraeus. Good results are also achieved with the metallic paste 6142 from DuPont. These parts can be laminated effectively and then burnt out and sintered together (co-firing).

The inside diameter ID of the spiral pulse generator is 10 mm. The width of the individual strips is likewise 10 mm. The film thickness is 50 μm, and the thickness of the two conductors is also in each case 50 μm. The charging voltage is 300 V. Under these conditions, the spiral pulse generator achieves an optimum for its properties with a number of turns per unit length of n=20 to 70.

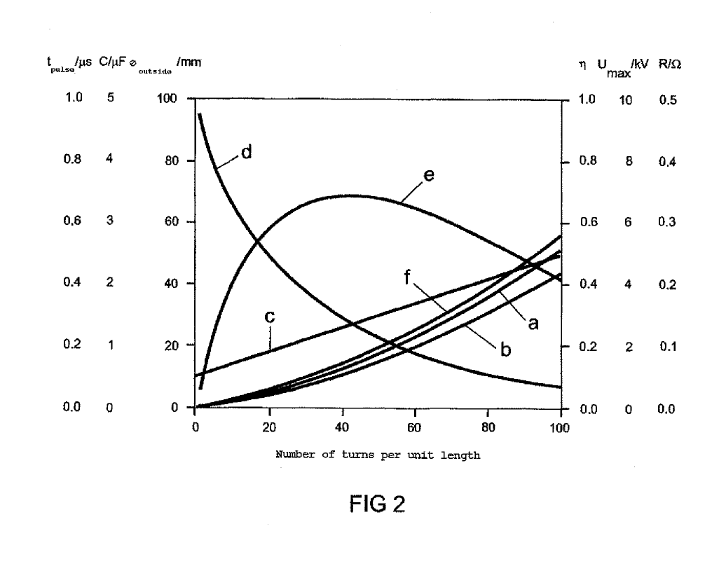

FIG. 2 shows the associated half value width of the high voltage pulse in μs (curve a), the total capacitance of the component in μF (curve b), the resultant outside diameter in mm (curve c), and the efficiency (curve d), the maximum pulse voltage (curve e) in kV, and the conductor resistance in Ω (curve f).

### First Embodiment

After the production of the actual spiral pulse generator, a partial ferrite layer of suitable thickness is now applied thereto in accordance with the invention. To this end, the spiral pulse generator is dipped into a low viscosity slurry made from ceramic ferrite material. After drying out the slurry, there is formed on the annular surface a ferritic layer that is subsequently sintered at temperatures between 800° C. and 900° C. The process can be repeated several times in order to form a thicker ferrite layer. However, a plurality of dipping processes can also take place between the sintering processes, in order to accelerate the entire coating process.

Owing to the fact that the ferrite layer is burnt in in a dedicated sintering process, a firm surface connection to the spiral pulse generator is formed. FIG. 9 shows a spiral pulse generator 31 having such a ferritic layer 35.

The following ferrites come into consideration as ferritic materials:

| Ceramic ferrite | Permeability μ |
|---|---|
| Ba hexaferrite | 20-100 |
| NiZnCu ferrite | 100-500 |
| MnZn ferrite | 200-3000 |

The substance systems of the hexaferrites and the NiZnCu ferrites in this case comprise all magnetically ferritic spinel structures.

In a preferred embodiment, the slurry systems contain at least one binder made from PVB (polyvinyl butyral), ethyl cellulose, epoxide, acrylate or a mixture of the aforenamed substances.

In a further preferred embodiment, the slurry systems contain at least one dispersant. By way of example, the dispersant can be oleic acid, menhaden oil (fish oil) or KD1, or a mixture thereof.

In a further preferred embodiment, the slurry systems contain at least one polar or one non-polar solvent or mixtures thereof.

In a further preferred embodiment, the slurry systems contain at least one softener such as, for example, phthalate compounds.

### Second Embodiment

In a second embodiment, the spiral pulse generator is completely or partially encased by a ferritic sealing compound.

The sealing compound consists of a polymeric substance system that is filled with ferritic powder at a fraction of 10% up to 80%. The spiral pulse generator itself in this case preferably consists of a capacitively acting ceramic material with an ∈ᵣ of 4 to 2000. Here, the ferritic sealing compound preferably has a permeability μᵣ from 1 to 5000.

The following polymeric substance systems come into consideration in principle for the binding:
One- and two-component systems based on acrylic resins.
One- and two-component systems based on epoxy resins.
One- and two-component systems based on polyurethane resins.
One- and two-component systems based on silicone resins.

The crosslinking of these sealing compounds can be performed via polymerization, polyaddition or polycondensation. The initialization of the crosslinking reaction is preferably performed in this case via UV sensitive or thermally activated catalysts or initiators.

The ferritic powder in this case consists of ceramic ferrites, metal ferrites or else of any desired mixture of the two materials. In this case, the ceramic ferrites are preferably from two ferrite classes:
spinel ferrites (Al-xBxFe204), where A=Ni, Mn and B=Cu, Zn, Co, Li,
hexaferrites of types M, W, X, Y, Z, U

In this case, the metal ferrites are preferably from the following metals:
AlNiCo
AlComax
MnBi
Ce(CuCo)₅
SmCo₅

Sm₂Co₁₇
Nd₂Fe₁₄B

The ferrite powder, which can consist of a mixture of abovenamed materials, is mixed with the polymeric compound in a suitable ratio. A good result is attained with, for example, a sealing compound made from 60% by volume MnZn ferrite (for example N27 from Epcos) and 40% by volume of epoxy resin (for example Vitralit 1605 from Panacol). The finished sintered spiral pulse generator is put into a preform, the electric connections being led out upward. The sealing compound is cast into this preform so that the spiral pulse generator is completely encased. Subsequently, the structure is completely cured for 30 minutes at 120° C.

Owing to the polymeric fraction of the sealing compound, this acts electrically like a homogeneous ferrite having an air gap, the air gap width being determined by the polymeric resin, whose μᵣ is approximately one. With this design, the impedance of the spiral pulse generator can be adapted to the inductance of the short circuit switch (usually a spark gap or a Zener diode using SiC technology). This adaptation is possible owing to the geometric design of the cast body, on the one hand, and on the other hand, by the magnetic properties of the sealing compound itself (ferrite material, ferrite material/polymer resin mixing ratio).

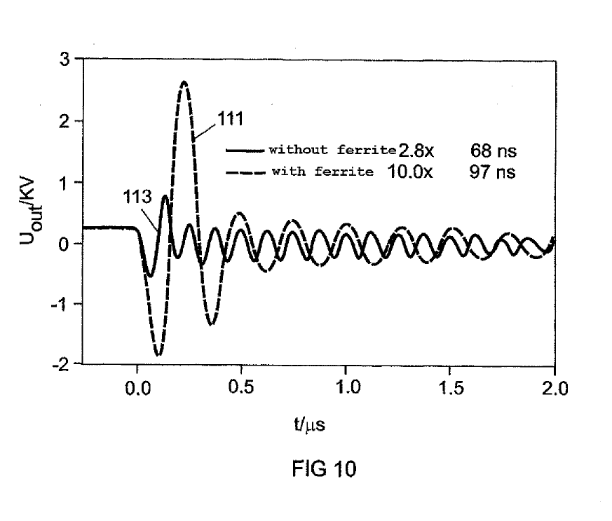

FIG. 10 shows the voltage profile across a spiral pulse generator that is connected as a starting transformer and is encased with a ferritic sealing compound (signal 111) in comparison to a spiral pulse generator without ferrite (signal 113). The higher generated starting voltage of the inventive spiral pulse generator as compared with a spiral pulse generator without ferrite casing is well in evidence. This results from the better adaptation of the impedance to the short circuit switch used. Furthermore, owing to the ferritic casing it is possible to adapt the oscillation frequency of the starting pulse to the conditions of the application so that further gains in efficiency of the overall system can be achieved here.

The advantages of the second embodiment lie in a cost effective mode of production, since the casting resins are more cost effective than adapted finished ferrite cores. The main advantage of the second embodiment is the simpler processing, since the final product is produced in a single machining step and can therefore be produced much more cost effectively. However, a product resulting from the second embodiment is not thermostable, and therefore not suitable for use in the outer bulb next to a high pressure discharge lamp burner. However, there are many other fields of use for such a spiral pulse generator, for example as an ignition coil in automobiles, as a high voltage source in consumer devices such as magic spheres etc.

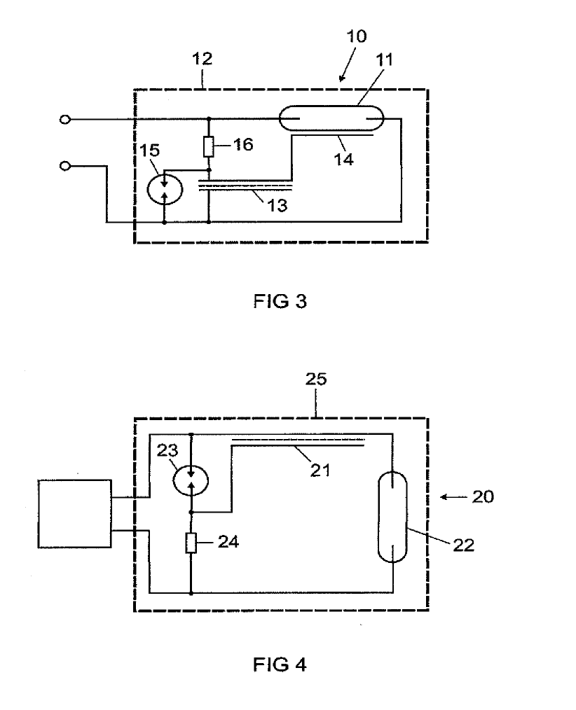

An inventive spiral pulse generator 31 according to the first embodiment is then preferably installed in a high pressure gas discharge lamp. FIG. 3 shows the basic design of a sodium high pressure lamp 10 having

a ceramic discharge vessel 11 and outer bulb 12 in which a spiral pulse generator 13 is integrated, a starting electrode 14 being fitted outside on the ceramic discharge vessel 11. The spiral pulse generator 13 is accommodated in the outer bulb with the spark gap 15 and the charging resistor 16.

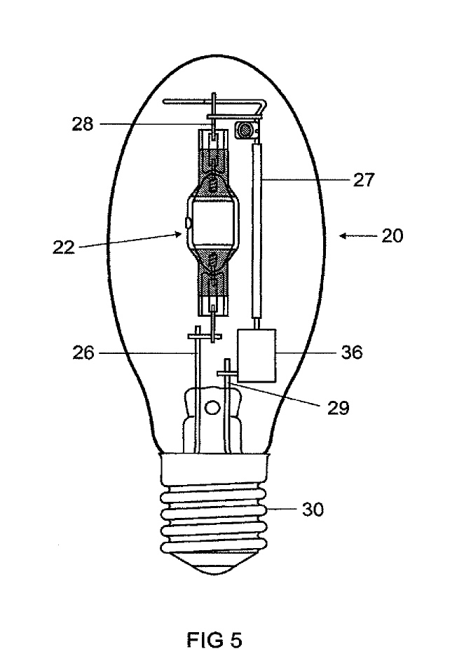

FIG. 4 shows the basic design of a metal halide lamp 20 having an integrated spiral pulse generator 31, no starting electrode being fitted outside on the discharge vessel 22, which can be fabricated from silica glass or ceramic. The spiral pulse generator 31 is accommodated in the outer bulb 25 with the spark gap 23 and the charging resistor 24.

FIG. 5 shows a metal halide lamp 20 having a discharge vessel 22 that is held in an outer bulb by two supply leads 26, 27. The first supply lead 26 is a short length of bent wire. The second 27 is essentially a rod that leads to the leadthrough 28 remote from the base. Arranged between the supply lead 29 from the base 30 and the rod 27 is a starting unit 36 that contains the spiral pulse generator 31, the spark gap 23 and the charging resistor 24, as indicated in FIG. 4.

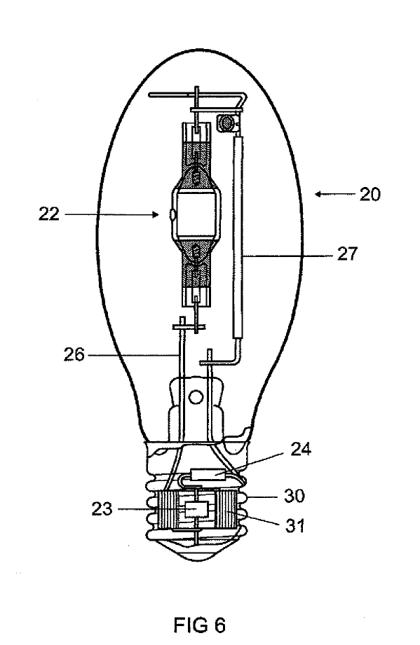

FIG. 6 shows a metal halide lamp 20 similar to that in FIG. 5 and having a discharge vessel 22 that is held by two supply leads 26, 27 in an outer bulb 25. The first supply lead 26 is a short length of bent wire. The second 27 is essentially a rod that leads to the leadthrough 28 remote from the base. Here, the starting unit is arranged in the base 30, specifically both the

spiral pulse generator 31, and the spark gap 23 and the charging resistor 24.

This technique can also be applied to electrodeless lamps, the spiral pulse generator being able to serve as starting aid.

Further applications of this compact high voltage pulse generator lie in the starting of other devices. The application is chiefly advantageous in the case of so called magic spheres, in the generation of X-ray pulses and the generation of electron beam pulses. Use in motor vehicles as a replacement for the customary ignition coils is also possible.

Use is made in this case of n of up to 500 as number of turns per unit length, and so the output voltage up to the order of magnitude of 100 kV is reached. The point is that the output voltage UA is given as a function of the charging voltage UL by UA=2×n×UL×n, the efficiency η being given by η=(AD−ID)/AD.

The invention develops particular advantages in cooperation with high pressure discharge lamps for automobile headlights that are filled with xenon under high pressure of preferably at least 3 bars, and metal halides. These are particularly difficult to start, because their starting voltage is more than 10 kV owing to the high xenon pressure. The spiral pulse generator can be arranged in the base of the lamp, or in an outer bulb of the lamp.

The invention develops very particular advantages in cooperation with high pressure discharge lamps that contain no mercury. Such lamps are particularly desirable for reasons of environmental protection. They contain

a suitable metal halide fill, and in particular an inert gas such as xenon under high pressure. Because of the lack of mercury, the starting voltage is particularly high. It is more than 20 kV. Here, as well, it is possible for a spiral pulse generator having an integrated charge resistor to be accommodated either in the base of the mercury free lamp, in an outer bulb of the lamp.

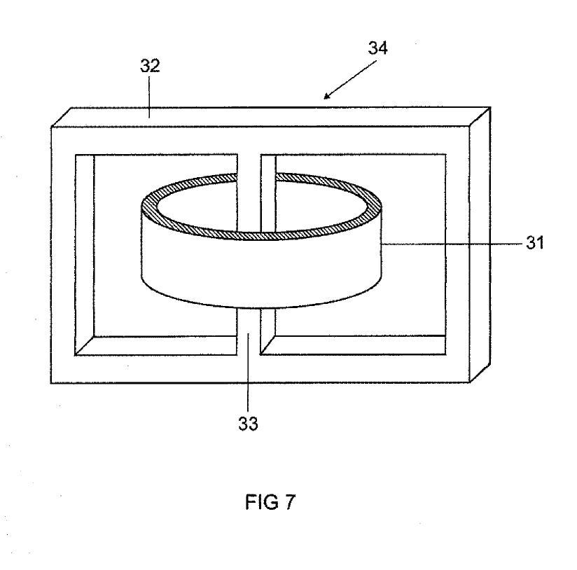

FIG. 7 shows in a schematic illustration a spiral pulse generator 31 that is surrounded by a ferrite core 34 in classical fashion as a double E core. The ferrite core 34 has a rectangular frame 32 and a central web 33 that passes through the cavity in the spiral pulse generator 31.

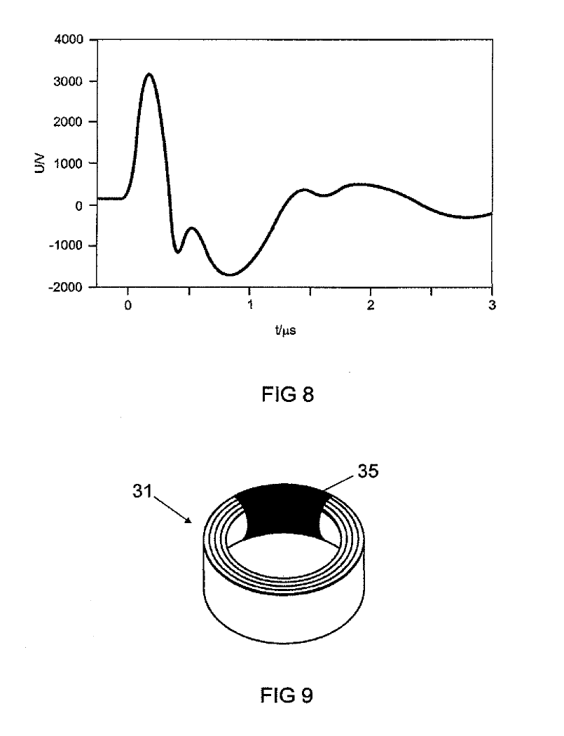

FIG. 8 shows as a function of time (in μs) the voltage profile (in V) across such a spiral pulse generator connected as a starting transformer.

1. A compact high voltage pulse generator based on a spiral pulse generator, wherein the spiral pulse generator is completely or partially surrounded by a ferritic material, the ferritic material being applied in a coating method as claimed in claim 5.

2. The high voltage pulse generator as claimed in claim 1, wherein the ferritic material is a ferritic ceramic layer applied in a dip coating method.

3. The high voltage pulse generator as claimed in claim 1, wherein the ferritic material is a ferritic sealing compound applied in a sealing coating method.

4. A starting unit based on a high voltage pulse generator as claimed in claim 1, further comprising at least one charging resistor and a switch.

5. A coating method for coating a spiral pulse generator with a ferritic layer, wherein the spiral pulse generator is surrounded by a ferritic compound that is cured by heat or UV radiation.

6. The coating method as claimed in claim 5, wherein the spiral pulse generator is dipped into a ferritic compound made from a low viscosity ferritic slurry, and is sintered at temperatures of 500° C.-900° C. after the drying of the slurry.

7. The coating method as claimed in claim 5, wherein the ferritic layer consists of a Ba hexaferrite, NiZnCu ferrite or MnZn ferrite compound.

8. The coating method as claimed in claim 6, wherein the low viscosity slurry consists of a slurry system having at least one binder made from PVB (polyvinyl butyral), ethyl cellulose, epoxide or acrylate, or can contain mixtures of the aforenamed substances as binders.

9. The coating method as claimed in claim 6, wherein the low viscosity slurry consists of a slurry system that contains as dispersants KD1 or oleic acid or menhaden oil or a mixture thereof.

10. The coating method as claimed in claim 6, wherein the low viscosity slurry consists of a slurry system that contains as solvent at least one polar or one non-polar solvent or a mixture of the two.

11. The coating method as claimed in claim 6, wherein the low viscosity slurry consists of a slurry system that contains at least one softener.

12. The coating method as claimed in claim 5, wherein the spiral pulse generator is surrounded in a sealing coating process by a ferritic sealing compound whose polymeric fraction is then crosslinked via polymerization, polyaddition or polycondensation.

13. The coating method as claimed in claim 12, wherein the crosslinking process is performed via UV sensitive or thermally activated catalysts or initiators.

14. The coating method as claimed in claim 12, wherein the ferritic sealing compound consists of a mixture of a polymeric sealing compound and a ferrite powder.

15. The coating method as claimed in claim 14, wherein the fraction of the ferrite powder referred to the total volume is between 10% by volume and 90% by volume.

16. The coating method as claimed in claim 14, wherein the polymeric sealing compound consists of one- or two-component systems based on acrylic resins, epoxy resins, polyurethane resins or silicone resins.

17. The coating method as claimed in claim 14, wherein the ferrite powder consists of ceramic spinel ferrites and/or ceramic hexaferrites.

18. The coating method as claimed in claim 14, wherein the ferrite powder consists of metal ferrites of the substance classes of AlNiCo, AlComax, MnBi, Ce(CuCo)₅, SmCo₅, Sm₂Co₁₇, Nd₂Fe₁₄B or of mixtures of these substance classes.

19. A high pressure discharge lamp having a discharge vessel that is accommodated in an outer bulb, there being integrated in the lamp a starting device that generates high voltage pulses in the lamp, wherein the starting device is a spiral pulse generator that has been produced using the coating method of claim 5.

20. The high pressure discharge lamp as claimed in claim 19, wherein the starting device is held by a frame.

21. The high pressure discharge lamp as claimed in claim 19, wherein the spiral pulse generator is produced from a heat resistant material.

22. The high pressure discharge lamp as claimed in claim 19, wherein the high voltage imparted by the spiral pulse generator acts directly on two electrodes in the discharge vessel.

23. The high pressure discharge lamp as claimed in claim 19, wherein the voltage imparted by the spiral pulse generator acts on an auxiliary starting electrode fitted outside on the discharge vessel.

24. The high pressure discharge lamp as claimed in claim 19, wherein the spiral pulse generator is accommodated in an outer bulb of the lamp.
